(19) United States
(12) Patent Application Publication
(10) Pub. No.: US 2026/0089951 A1
(43) Pub. Date: Mar. 26, 2026

(54) SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventors: Tae Young KIM, Suwon-si (KR); Kwang-Soo KIM, Suwon-si (KR); Hyun-Mook CHOI, Suwon-si (KR)

(73) Assignee: SAMSUNG ELECTRONICS CO., LTD., Suwon-si (KR)

(21) Appl. No.: 19/293,442

(22) Filed: Aug. 7, 2025

(30) Foreign Application Priority Data
Sep. 24, 2024 (KR) 10-2024-0129157

(51) Int. Cl. H10B 43/27; G11C 16/04; H01L 23/00; H01L 25/18; H10B 41/10; H10B 41/27; H10B 41/35; H10B 41/41; H10B 43/10; H10B 43/35; H10B 43/40; H10B 80/00; H10D 80/30

(52) U.S. Cl. CPC H10B 43/27; G11C 16/0483; H10B 41/10; H10B 41/27; H10B 41/35; H10B 41/41; H10B 43/10; H10B 43/35; H10B 43/40; H10B 80/00; H10D 80/30; H10W 90/00; H10W 90/20; H10W 90/732; H10W 90/734

(57) ABSTRACT

A semiconductor device includes a cell substrate, a mold structure including a plurality of gate electrodes stacked on the cell substrate, a channel structure passing through the mold structure, a string selection line disposed on an upper surface of the channel structure, and a string selection channel structure being in contact with the channel structure by passing through the string selection line, wherein the string selection channel structure includes hafnium oxide different from a material of the channel structure.

### CROSS-REFERENCE TO RELATED APPLICATION

This application claims priority from Korean Patent Application No. 10-2024-0129157, filed on Sep. 24, 2024 in the Korean Intellectual Property Office and all the benefits accruing therefrom under 35 U.S.C. 119, the contents of which are incorporated herein by reference in its entirety.

### BACKGROUND

The present disclosure relates to a semiconductor memory device and an electronic system including the same.

In order to meet consumer demands for high performance and low price, it may be required to increase the degree of integration in semiconductor memory devices. Since the degree of integration affects the price of a product, an increased degree of integration is a critical factor in reducing costs.

In conventional two-dimensional or planar semiconductor memory devices, since the degree of integration is mainly determined by an area occupied by a unit memory cell, the two-dimensional or planar semiconductor devices are greatly affected by a level of technology for forming a fine pattern. However, the need for ultra-high-priced equipment to create the fine pattern limits further integration of the two-dimensional semiconductor devices. Accordingly, three-dimensional semiconductor memory devices with memory cells arranged in a three-dimensional configuration have been proposed.

### SUMMARY

One or more embodiments of the present disclosure provide a semiconductor memory device with improved electrical characteristics and reliability.

Further, one or more embodiments provide an electronic system including a semiconductor memory device with improved electrical characteristics and reliability.

According to an aspect of the present disclosure, a semiconductor memory device may include: a cell substrate; a mold structure comprising a plurality of gate electrodes stacked on the cell substrate; a channel structure passing through the mold structure; a string selection line disposed on an upper surface of the channel structure; and a string selection channel structure that passes through the string selection line and is in contact with the channel structure, wherein the string selection channel structure comprises hafnium oxide that is different from a material of the channel structure.

According to another aspect of the present disclosure, a semiconductor memory device may include: a cell substrate, a mold structure including a plurality of gate electrodes stacked on the cell substrate, a channel structure extending perpendicular to the cell substrate by passing through the mold structure, a string selection line disposed on the channel structure, and a string selection channel structure extending perpendicular to the cell substrate from the channel structure by passing through the string selection line, wherein the channel structure includes a first channel pattern, and a first channel pattern insulating film between the first channel pattern and the plurality of gate electrodes, the string selection channel structure includes a second channel pattern connected to the channel structure, and a second channel pattern insulating film, which includes a ferroelectric material, between the second channel pattern and the string selection line, and a thickness of the second channel pattern insulating film is less than a thickness of the first channel pattern insulating film.

According to another aspect of the present disclosure, an electronic system may include: a main board, a semiconductor memory device on the main board, and a processor that is electrically connected to the semiconductor memory device and is provided on the main board, wherein the semiconductor memory device includes a cell substrate, a mold structure including a plurality of gate electrodes stacked on the cell substrate, a first channel structure extending to the cell substrate by passing through the mold structure, a conductive line on the first channel structure, and a second channel structure extending to the cell substrate from the first channel structure by passing through the conductive line. The first channel structure includes a first filling pattern, a first channel pattern surrounding the first filling pattern, and a first channel pattern insulating film between the first channel pattern and the plurality of gate electrodes. The second channel structure includes a second filling pattern, a second channel pattern surrounding the second filling pattern and being in contact with the first channel structure, and a second channel pattern insulating film between the second channel pattern and the conductive line. A thickness of the second channel pattern insulating film is less than a thickness of the first channel pattern insulating film, and the second channel pattern insulating film includes a ferroelectric material different from that of the first channel pattern insulating film.

According to another aspect of the present disclosure, a memory may include: a string selection transistor (SST) including a string selection line (SSL) and a string selection channel structure (SCH); a mold structure (MS) disposed on the SST and including a mold channel structure (CH) that at least partially overlaps with the SCH. The mold channel structure may include: a filling pattern; a channel pattern covering an outer surface of the filling pattern; and a plurality of channel insulating films sequentially stacked on an outer surface of the channel pattern. At least one of inner channel insulating films among the plurality of channel insulating films may include hafnium oxide.

### BRIEF DESCRIPTION OF DRAWINGS

FIG. 1 is an exemplary block diagram illustrating a semiconductor memory device according to some embodiments.

FIG. 2 is an exemplary circuit view illustrating a semiconductor memory device according to some embodiments of the present disclosure.

FIG. 3 is an exemplary layout view illustrating a semiconductor memory device according to some embodiments.

FIG. 4 is a cross-sectional view taken along line I-I′ of FIG. 3.

FIG. 5 is an enlarged view illustrating a region Q1 of FIG. 4.

FIG. 6 is an enlarged view illustrating a region A of FIG. 4.

FIG. 7 is an enlarged view illustrating a region Q2 of FIG. 4.

FIG. 8 is another exemplary cross-sectional view illustrating a semiconductor memory device according to some embodiments.

FIG. 9 is an enlarged view illustrating a region Q3 of FIG. 8.

FIG. 10 is another exemplary cross-sectional view illustrating a semiconductor memory device according to some embodiments.

FIG. 11 is an enlarged view illustrating a region Q4 of FIG. 10.

FIG. 12 is another exemplary cross-sectional view illustrating a semiconductor memory device according to some embodiments.

FIG. 13 is an enlarged view illustrating a region Q5 of FIG. 12.

FIGS. 14 to 23 are views illustrating a method of fabricating a semiconductor memory device according to some embodiments.

FIGS. 24 to 26 are views illustrating a method of fabricating a semiconductor memory device according to some embodiments.

FIG. 27 is an exemplary block diagram illustrating an electronic system according to some embodiments.

FIG. 28 is an exemplary perspective view illustrating an electronic system according to some embodiments.

FIG. 29 is a schematic cross-sectional view taken along line II-II′ of FIG. 28.

### DETAILED DESCRIPTION

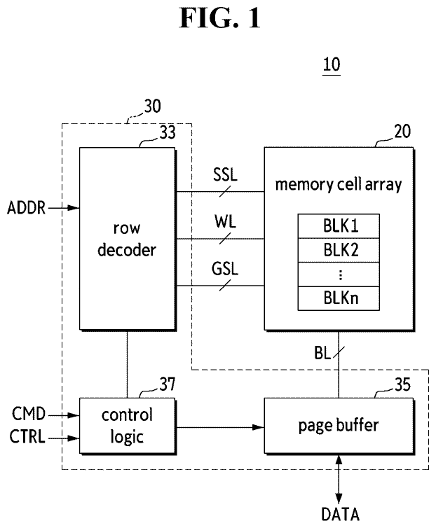

FIG. 1 is an exemplary block diagram illustrating a semiconductor memory device according to some embodiments.

Referring to FIG. 1, a semiconductor memory device 10 according to some embodiments includes a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL and at least one ground selection line GSL. In detail, the memory cell blocks BLK1 to BLKn may be connected to a row decoder 33 through the word line WL, the string selection line SSL and the ground selection line GSL. In addition, the memory cell blocks BLK1 to BLKn may be connected to a page buffer 35 through the bit line BL.

The peripheral circuit 30 may receive an address ADDR, a command CMD and a control signal CTRL from the outside of the semiconductor memory device 10, and may transmit and receive data DATA to and from an external device of the semiconductor memory device 10. The peripheral circuit 30 may include a control logic 37, a row decoder 33 and a page buffer 35. The peripheral circuit 30 may further include various sub-circuits such as an input/output circuit, a voltage generating circuit for generating various voltages required for an operation of the semiconductor memory device 10 and an error correction circuit for correcting an error of the data DATA read from the memory cell array 20.

The control logic 37 may be connected to the row decoder 33, the page buffer 35, the input/output circuit and the voltage generating circuit. The control logic 37 may control the overall operation of the semiconductor memory device 10. The control logic 37 may generate various internal control signals used in the semiconductor memory device 10 in response to the control signal CTRL. For example, the control logic 37 may adjust a voltage level provided to the word line WL and the bit line BL when a memory operation such as a program operation or an erase operation is performed.

The row decoder 33 may select at least one of the plurality of memory cell blocks BLK1 to BLKn in response to the address ADDR, and may select at least one word line WL, at least one string selection line SSL and at least one ground selection line GSL of the selected memory cell blocks BLK1 to BLKn. In addition, the row decoder 33 may transfer a voltage for performing the memory operation to the word line WL of the selected memory cell blocks BLK1 to BLKn.

The page buffer 35 may be connected to the memory cell array 20 through the bit line BL. The page buffer 35 may operate as a write driver or a sense amplifier. In detail, when a program operation is performed, the page buffer 35 may operate as a write driver to apply a voltage according to the data DATA to be stored in the memory cell array 20, to the bit line BL. Meanwhile, when a read operation is performed, the page buffer 35 may operate as a sense amplifier to sense the data DATA stored in the memory cell array 20.

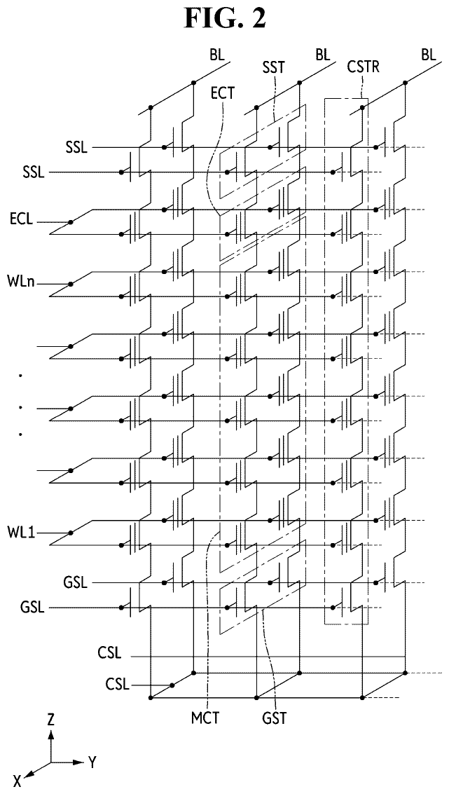

FIG. 2 is an exemplary circuit view illustrating a semiconductor memory device according to some embodiments of the present disclosure.

Referring to FIG. 2, the memory cell array (e.g., the memory cell array 20 of FIG. 1) of a semiconductor memory device according to some embodiments includes a common source line CSL, a plurality of bit lines BL and a plurality of cell strings CSTR.

The common source line CSL may extend in a second direction Y. In some embodiments, a plurality of common source lines CSL may be arranged two-dimensionally. For example, the plurality of common source lines CSL may be spaced apart from each other and may extend in the second direction Y. The electrically same voltage may be applied to the common source lines CSL, or different voltages may be applied to the common source lines CSL and controlled separately.

The plurality of bit lines BL may be arranged two-dimensionally. For example, the bit lines BL may respectively extend in a first direction X crossing the second direction Y by being spaced apart from each other. The plurality of cell strings CSTR may be connected to the respective bit lines BL in parallel. The cell strings CSTR may be commonly connected to the common source line CSL. That is, the plurality of cell strings CSTR may be disposed between the bit lines BL and the common source line CSL.

Each of the cell strings CSTR may include a ground selection transistor GST connected to the common source line CSL, a string selection transistor SST connected to the bit line BL and a plurality of memory cell transistors MCT disposed between the ground selection transistor GST and the string selection transistor SST. Each of the memory cell transistors MCT may include a data storage element. The ground selection transistor GST, the string selection transistor SST and the memory cell transistors MCT may be connected in series.

The common source line CSL may be commonly connected to sources of the ground selection transistors GST. In addition, the ground selection line GSL, a plurality of word lines WL1 to WLn and the string selection line SSL may be disposed between the common source line CSL and the bit line BL. The ground selection line GSL may be used as a gate electrode of the ground selection transistor GST, the word lines WL1 to WLn may be used as gate electrodes of the memory cell transistors MCT, and the string selection line SSL may be used as a gate electrode of the string selection transistor SST.

In some embodiments, an erase control transistor ECT may be disposed between the common source line CSL and the ground selection transistor GST. The common source line CSL may be commonly connected to sources of the erase control transistors ECT. An erase control line ECL may be disposed between the common source line CSL and the ground selection line GSL. The erase control line ECL may be used as a gate electrode of the erase control transistor ECT. The erase control transistor ECT may generate a gate induced drain leakage (GIDL) to perform an erase operation of the memory cell array.

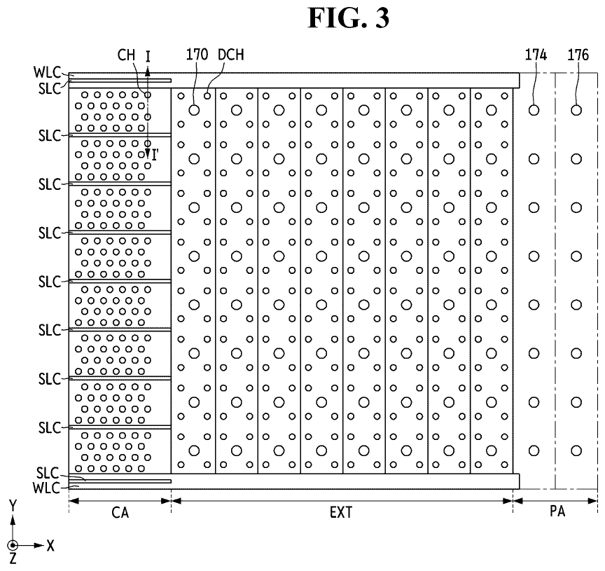

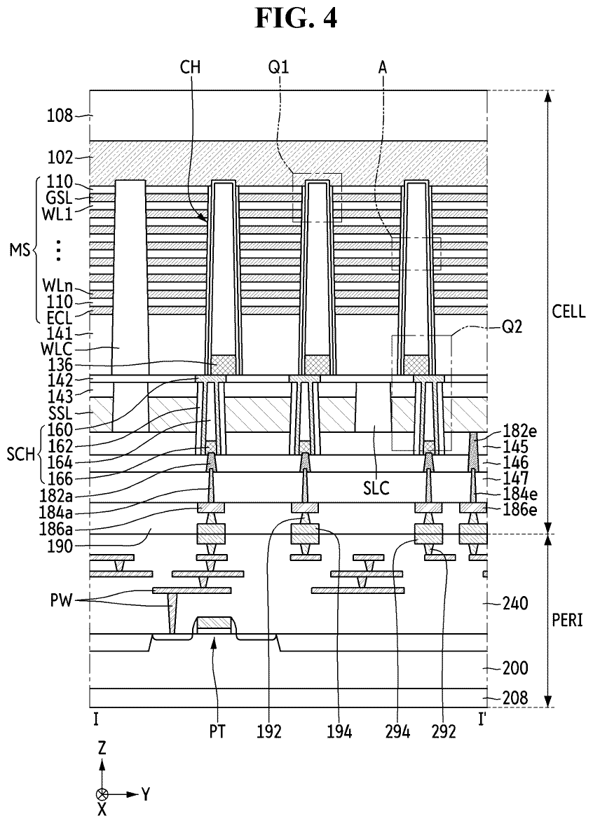

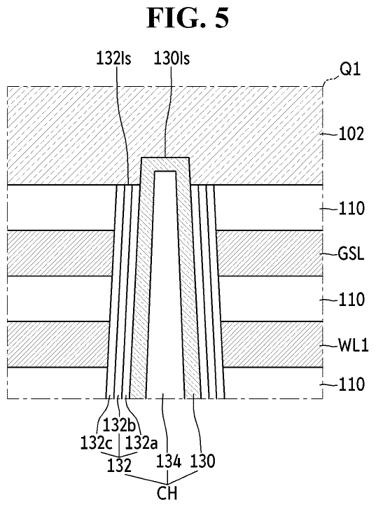

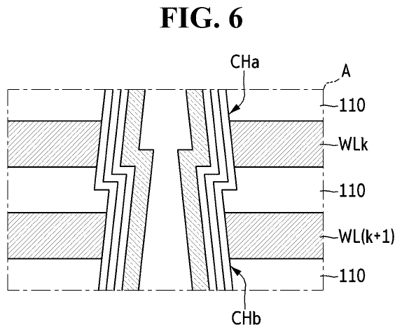

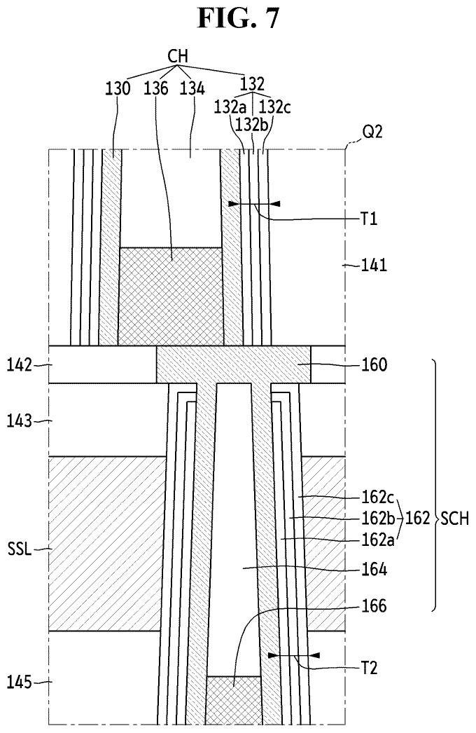

FIG. 3 is an exemplary layout view illustrating a semiconductor memory device according to some embodiments. FIG. 4 is a cross-sectional view taken along line I-I′ of FIG. 3. FIG. 5 is an enlarged view illustrating a region Q1 of FIG. 4. FIG. 6 is an enlarged view illustrating a region A of FIG. 4. FIG. 7 is an enlarged view illustrating a region Q2 of FIG. 4.

Referring to FIGS. 3 and 4, the semiconductor memory device according to some embodiments includes a memory cell structure CELL and a peripheral circuit structure PERI.

The memory cell structure CELL may include a cell substrate 102, a mold structure MS, first to sixth interlayer insulating films 141 to 147, a channel structure CH, a word line cutting structure WLC, a string selection line SSL, a string separation structure SLC, a string selection channel structure SCH, a cell contact 170, a source contact 174, an input/output contact 176, first metal patterns 186a and 186e, a first interconnection insulating film 190, a first bonding via 192, and a first bonding metal 194.

The cell substrate 102 may include a cell array area CA, an extension area EXT, and a pad area PA.

The memory cell array (e.g., 20 of FIG. 1) including a plurality of memory cells may be disposed on the cell array area CA. For example, the channel structure CH, the first metal pattern 186a, the ground selection line GSL, the word lines WL1 to WLn and the erase control line ECL, and the string selection line SSL, which will be described later, may be disposed on the cell array area CA. In the following description, a surface of the cell substrate 102 on which the memory cell array is disposed may be referred to as a front side of the cell substrate 102. In contrast, a surface of the cell substrate 102, which are opposite to the front side of the cell substrate 102, may be referred to as a back side of the cell substrate 102.

The extension area EXT may be disposed around the cell array area CA. The extension area EXT may surround the cell array area CA, for example, when viewed in a plan view. The ground selection line GSL, the word lines WL1 to WLn, and the erase control line ECL, which will be described later, may be stacked on the extension area EXT in a stepwise shape.

The pad area PA may be disposed outside the extension area EXT, for example. The pad area PA may surround the extension area EXT, for example, when viewed in a plan view. The source contact 174 and the input/output contact 176, which will be described later, may be disposed on the pad area PA.

In some embodiments, the cell substrate 102 may include a source layer. For example, the source layer of the cell substrate 102 may be provided in the cell array area CA and the pad area PA. In some embodiments, the source layer of the cell substrate 102 may be formed on the cell array area CA, but may not be formed on the extension area EXT.

The source layer of the cell substrate 102 may include a conductive material, for example, polysilicon doped with impurities, metal, or the like, but is not limited thereto. The source layer of the cell substrate 102 may be provided as a common source line (for example, CSL of FIG. 2) of the semiconductor memory device.

The mold structure MS may be disposed on the front side of the cell substrate 102. The mold structure MS may include a plurality of ground selection line GSL, the word lines WL1 to WLn, and the erase control line ECL and a plurality of mold insulating films 110, which are stacked on the cell substrate 102. Each of the ground selection line GSL, the word lines WL1 to WLn, and the erase control line ECL and each of the mold insulating films 110 may have a layered structure extending in parallel with the front side of the cell substrate 102. The ground selection line GSL, the word lines WL1 to WLn, and the erase control line ECL may be spaced apart from one another by the mold insulating film 110 and sequentially stacked on the cell substrate 102.

The ground selection line GSL, the word lines WL1 to WLn, and the erase control line ECL may be stacked on the extension area EXT in a stepwise shape. For example, the ground selection line GSL, the word lines WL1 to WLn, and ECL may extend at different lengths in the first direction X to have a step difference. The ground selection line GSL, the word lines WL1 to WLn, and the erase control line ECL may extend at different lengths in the second direction Y to have a step difference.

Hereinafter, a thickness may be based on a third direction Z. The third direction Z may cross the first direction X and the second direction Y. The third direction Z may be a direction perpendicular to the front side of the cell substrate 102. The first direction X and the second direction Y may be directions parallel with the front side of the cell substrate 102. Hereinafter, an upper surface, a lower surface, an upper portion and a lower portion will be based on the third direction Z.

In some embodiments, gate electrodes of the mold structure MS may include the ground selection line GSL, the word lines WL1 to WLn, and the erase control line ECL, which are sequentially stacked on the cell substrate 102. The number and arrangement of the ground selection line GSL, the word lines WL1 to WLn, and the erase control line ECL are only exemplary and are not limited to the shown example. In some other embodiments, the erase control line ECL may be omitted. In some other embodiments, the gate electrodes of the mold structure MS may further include a dummy word line.

Each of the ground selection line GSL, the word lines WL1 to WLn, and the erase control line ECL may include a conductive material, for example, metal such as tungsten (W), cobalt (Co) and nickel (Ni), or a semiconductor material such as silicon, but is not limited thereto. For example, each of the ground selection line GSL, the word lines WL1 to WLn, and the erase control line ECL may include tungsten (W). The ground selection line GSL, the word lines WL1 to WLn, and the erase control line ECL may be, for example, multi-layers. For example, when the ground selection line GSL, the word lines WL1 to WLn, and the erase control line ECL are multi-layers, the ground selection line GSL, the word lines WL1 to WLn, and the erase control line ECL may include a gate electrode barrier layer and a gate electrode filling layer.

The mold insulating film 110 may be stacked alternately with the ground selection line GSL, the word lines WL1 to WLn, and the erase control line ECL. The mold insulating film 110 may be stacked on the extension area EXT in a stepwise shape. For example, the mold insulating film 110 may extend at different lengths in the first direction X to have a step difference. The mold insulating film 110 may extend at different lengths even in the second direction Y to have a step difference.

The mold insulating film 110 may include an insulating material, for example, at least one of silicon oxide, silicon nitride, or silicon oxynitride, but is not limited thereto. For example, the mold insulating film 110 may include silicon oxide.

The first interlayer insulating film 141 may be disposed on the cell substrate 102 to cover the mold structure MS.

The channel structure CH may be disposed on the cell array area CA. Each of a plurality of channel structures CH may extend in the third direction Z to pass through the mold structure MS. For example, the channel structure CH may be a pillar-shaped (e.g., cylindrical-shaped) structure extending in the third direction Z. Accordingly, the channel structure CH may cross each of the ground selection line GSL, the word lines WL1-WLn, and the erase control line ECL. In some embodiments, a width of the channel structure CH may be reduced toward the cell substrate 102.

As shown in FIG. 5, the channel structure CH may include a first channel pattern 130 and a first channel pattern insulating film 132.

The first channel pattern 130 may extend in the third direction Z to pass through the mold structure MS. The first channel pattern 130 may have, for example, a cup shape. As another example, the first channel pattern 130 may have various shapes such as a cylindrical shape, a quadrangular barrel shape and a filled pillar shape.

The first channel pattern 130 may include, for example, a semiconductor material such as monocrystalline silicon, polycrystalline silicon, an organic semiconductor material and a carbon nanostructure.

The first channel pattern insulating film 132 may be interposed between the first channel pattern 130 and each of the ground selection line GSL, the word lines WL1 to WLn, and the erase control line ECL. For example, the first channel pattern insulating film 132 may extend along at least a portion of an outer side of the first channel pattern 130.

In some embodiments, the first channel pattern insulating film 132 may be formed of a multi-layer. For example, as shown in FIG. 5, the first channel pattern insulating film 132 may include a (1_1)th insulating film 132a, a (1_2)th insulating film 132b, and a (1_3)th insulating film 132c, which are sequentially stacked on the outer side of the first channel pattern 130.

The (1_1)th insulating film 132a may include oxide, the (1_2)th insulating film 132b may include nitride, and the (1_3)th insulating film 132c may include oxide. The (1_1)th insulating film 132a may mean a tunnel insulating film, the (1_2)th insulating film 132b may mean a charge storage film, and the (1_3)th insulating film 132c may mean a blocking insulating film.

In detail, the (1_1)th insulating film 132a may include, for example, silicon oxide or a high-k material (e.g., aluminum oxide (Al₂O₃) or hafnium oxide (HfO₂)) having a dielectric constant higher than that of silicon oxide. The (1_2)th insulating film 132b may include, for example, silicon nitride. The (1_3)th insulating film 132c may include, for example, silicon oxide or a high-k material (e.g., aluminum oxide (Al₂O₃) or hafnium oxide (HfO₂)) having a dielectric constant higher than that of silicon oxide.

In some embodiments, the channel structure CH may further include a first filling pattern 134. The first filling pattern 134 may fill the inside of the first channel pattern 130 having a cup shape. The first channel pattern 130 may surround an outer sidewall of the first filling pattern 134. The first filling pattern 134 may include an insulating material, for example, silicon oxide.

The source layer of the cell substrate 102 may be electrically connected to the first channel pattern 130 of each channel structure CH. In some embodiments, a portion of the first channel pattern 130 may be disposed in the source layer of the cell substrate 102. A lower surface 1301s of the first channel pattern 130 may be disposed in the source layer of the cell substrate 102.

The first channel pattern insulating film 132 may extend along a portion of a side of the first channel pattern 130. The first channel pattern insulating film 132 may expose a lower portion of the first channel pattern 130. The first channel pattern insulating film 132 may expose the lower surface 1301s of the first channel pattern 130 and a portion of the side of the first channel pattern 130. The lower surface 1301s of the first channel pattern 130 may be disposed below a lower surface 1321s of the first channel pattern insulating film 132. The lower surface 1301s of the first channel pattern 130 may be in contact with the source layer of the cell substrate 102. A portion of the side of the first channel pattern 130 may be in contact with the source layer of the cell substrate 102.

For example, the lower surface 1321s of the first channel pattern insulating film 132 may be flat. Also, for example, the lower surface 1321s of the first channel pattern insulating film 132 may have a step difference. For example, a lower surface of the (1_1)th insulating film 132a may be disposed below a lower surface of the (1_2)th insulating film 132b, and the lower surface of the (1_2)th insulating film 132b may be disposed below a lower surface of the (1_3)th insulating film 132c.

In some embodiments, the channel structure CH may further include a first channel pad 136. The first channel pad 136 may be electrically connected to the first channel pattern 130. The first channel pad 136 may include, for example, polysilicon doped with impurities.

In some embodiments, the plurality of channel structures CH may be arranged in a zigzag shape or a honeycomb shape. For example, as shown in FIG. 3, the plurality of channel structures CH may be arranged to cross each other in the first direction X and the second direction Y, which are parallel with the upper surface of the cell substrate 102. The channel structure CH may further improve the degree of integration of the semiconductor memory device. The number and arrangement of channel structures CH are only exemplary, and are not limited to the shown example.

In some embodiments, the dummy channel structure DCH may be disposed in the mold structure MS of the extension area EXT. For example, the dummy channel structure DCH may have a shape similar to that of the channel structure CH.

Regarding to FIGS. 4 and 5, the semiconductor memory device may include a string selection transistor (SST) including a string selection line (SSL) and a string selection channel structure (SCH). The string selection transistor may perform an inhibit operation that prevents the selection of a specific cell while allowing another cell to be selected. The semiconductor memory device may further include a mold structure (MS) disposed on the string selection transistor and including a mold channel structure (CH) that at least partially overlaps with the SCH. The mold channel structure may include: a filling pattern (e.g., the first filling pattern 134), a channel pattern (e.g., the first channel pattern 130) covering an outer surface of the filling pattern; and a plurality of channel insulating films (e.g., the insulating films 132a, 132b, 132c) sequentially stacked on an outer surface of the channel pattern. At least one of inner channel insulating films (e.g., the insulating film 132b) among the plurality of channel insulating films may include hafnium oxide. The structure and materials of plurality of channel insulating films may enable a reduction in Equivalent oxide Thickness (EOT), thereby lowering a program voltage required to control electron flow in a memory cell.

Referring to FIG. 6, in some embodiments, the channel structure CH may include a first channel CHa and a second channel CHb, which are connected to each other. For example, the channel structure CH may be formed through a process for the first channel CHa and a process for the second channel CHb. The first channel CHa may be a lower portion of the channel structure CH, and the second channel CHb may be an upper portion of the channel structure CH. A width of the first channel CHa may be greater than a width of the second channel CHb at a boundary between the first channel CHa and the second channel CHb. The channel structure CH may have a bent portion at the boundary between the first channel CHa and the second channel CHb.

In addition, a word line positioned near the boundary between the first channel CHa and the second channel CHb may be a dummy word line. For example, a word line WLk (k is a natural number less than n) and a word line WL(k+1), which form the boundary of the first channel CHa and the second channel CHb, may be dummy word lines. In this case, data may not be stored in memory cells connected to the dummy word line. Alternatively, the number of pages corresponding to memory cells connected to the dummy word line may be less than the number of pages corresponding to memory cells connected to the general word line. A voltage level applied to the dummy word line may be different from a voltage level applied to the general word line.

Referring back to FIGS. 3 to 5, the word line cutting structure WLC may extend in the first direction X to cut the mold structure MS on the cell array area CA and the extension area EXT. Also, a plurality of word line cutting structures WLC may be spaced apart from each other and may extend in parallel in the first direction X. The mold structure MS may be divided by the word line cutting structure WLC to form a plurality of memory cell blocks (e.g., BLK1 to BLKn of FIG. 1). For example, two adjacent word line cutting structures WLC may define one memory cell block therebetween. The plurality of channel structures CH may be disposed in each memory cell block defined by the word line cutting structure WLC. In some embodiments, a width of the word line cutting structure WLC may be reduced toward the cell substrate 102.

The word line cutting structure WLC may extend in the first direction X to cut the source layer of the cell substrate 102. For example, a lower surface of the word line cutting structure WLC may be lower than an upper surface of the source layer of the cell substrate 102. For another example, the lower surface of the word line cutting structure WLC may be disposed on substantially the same plane as the lower surface of the source layer of the cell substrate 102.

In some embodiments, the word line cutting structure WLC may include an insulating material. For example, the word line cutting structure WLC may include at least one of silicon oxide, silicon nitride or silicon oxynitride.

The second interlayer insulating film 142 and the third interlayer insulating film 143 may be disposed on the mold structure MS. The second interlayer insulating film 142 may be disposed on the first interlayer insulating film 141, and the third interlayer insulating film 143 may be disposed on the second interlayer insulating film 142.

The string selection line SSL may be disposed on the mold structure MS. The string selection line SSL may be disposed on the third interlayer insulating film 143. For example, the string selection line SSL may be provided in the cell array area CA. For example, an end portion of the string selection line SSL in a horizontal direction may be provided in the cell array area CA.

The string selection line SSL may be stacked in a stepwise shape together with the ground selection line GSL, the word lines WL1 to WLn, and the erase control line ECL. For example, the string selection line SSL may extend at different lengths in the first direction X to have a step difference. The string selection line SSL may extend at different lengths in the second direction Y to have a step difference.

For example, a thickness of the string selection line SSL in the third direction Z may be greater than a thickness of each of the ground selection line GSL, the word lines WL1 to WLn, and the erase control line ECL in the third direction Z.

The string selection line SSL may include a conductive material. The string selection line SSL may include a semiconductor material such as polycrystalline silicon or monocrystalline silicon, and the semiconductor material may be an undoped material or a material containing p-type or n-type impurities. The string selection line SSL may include, for example, polysilicon.

The string separation structure SLC may extend in the first direction X to separate the string selection line SSL on the cell array area CA, as shown in FIG. 3. Also, a plurality of string separation structures SLC may be spaced apart from each other in the second direction Y, and may extend in parallel in the first direction X. A memory cell block defined by the word line cutting structure WLC may be divided by the string separation structure SLC to form a plurality of string areas. For example, the string separation structure SLC may define eight string areas in one memory cell block. At least a portion of the string separation structure SLC closest to the word line cutting structure WLC may overlap the word line cutting structure WLC in the third direction Z. Alternatively, the string separation structure SLC closest to the word line cutting structure WLC may not overlap the word line cutting structure WLC in the third direction Z.

The string separation structure SLC may pass through the string selection line SSL. The string separation structure SLC may further pass through, for example, the third interlayer insulating film 143. In some embodiments, a width of the string separation structure SLC may be reduced toward the cell substrate 102.

The string separation structure SLC may include an insulating material, for example, at least one of silicon oxide, silicon nitride, or silicon oxynitride.

The string selection channel structure SCH may be disposed on the cell array area CA. The string selection channel structure SCH may extend in the third direction Z to pass through the string selection line SSL. The string selection channel structure SCH may be disposed on the channel structure CH by passing through the string selection line SSL. The fourth interlayer insulating film 145 may be disposed on the string selection line SSL. The string selection channel structure SCH may pass through the fourth interlayer insulating film 145, the string selection line SSL, the third interlayer insulating film 143 and the second interlayer insulating film 142. In some embodiments, a width of the string selection channel structure SCH may be reduced toward the cell substrate 102.

The string selection channel structure SCH may include a second channel pattern 160, a second channel pattern insulating film 162, a second filling pattern 164, and a second channel pad 166.

The second channel pattern 160 may extend in the third direction Z to pass through the string selection line SSL. The second channel pattern 160 may be in contact with the first channel pattern 130 and the first channel pad 136 of the channel structure CH. The second channel pattern 160 may be electrically connected to the first channel pattern 130 and the first channel pad 136. Therefore, the string selection channel structure SCH may be electrically connected to the channel structure CH.

In some embodiments, the second channel pattern 160 in the second interlayer insulating film 142 may have a shape protruded toward the second interlayer insulating film 142. For example, the second channel pattern 160 may have a cup shape in which its width is reduced as it approaches the mold structure MS, but may have a width increased within the second interlayer insulating film 142.

The second channel pattern 160 may include, for example, a semiconductor material such as monocrystalline silicon, polycrystalline silicon, an organic semiconductor material, and a carbon nanostructure.

The second channel pattern insulating film 162 may be interposed between the second channel pattern 160 and the string selection line SSL. For example, the second channel pattern insulating film 162 may extend along an outer sidewall of the second channel pattern 160 within the third interlayer insulating film 143, the string selection line SSL and the fourth interlayer insulating film 145.

In some embodiments, the second channel pattern insulating film 162 may be formed of a multi-film. For example, as shown in FIG. 7, the second channel pattern insulating film 162 may include a (2_1)th insulating film 162a, a (2_2)th insulating film 162b, and a (2_3)th insulating film 162c, which are sequentially stacked on the outer side of the second channel pattern 160.

In detail, the (2_1)th insulating film 162a may include oxide, the (2_2)th insulating film 162b may include hafnium oxide, and the (2_3)th insulating film 162c may include oxide.

The (2_1)th insulating film 162a may include, for example, silicon oxide or a high-k material (e.g., aluminum oxide (Al₂O₃) or hafnium oxide (HfO₂)) having a dielectric constant higher than that of silicon oxide.

The (2_2)th insulating film 162b may include hafnium oxide containing at least one of silicon (Si), zirconium (Zr), aluminum (Al), lanthanum (La), niobium (Nb) or yttrium (Y). For example, the (2_2)th insulating film 162b may include hafnium oxide doped with at least one of silicon (Si) or zirconium (Zr). Alternatively, the (2_2)th insulating film 162b may include hafnium oxide doped with at least one of lanthanum (La), niobium (Nb) or yttrium (Y).

The (2_3)th insulating film 162c may include, for example, silicon oxide or a high-k material (e.g., aluminum oxide (Al₂O₃) or hafnium oxide (HfO₂)) having a dielectric constant higher than that of silicon oxide.

The second channel pattern insulating film 162 may include hafnium oxide different from that of the first channel pattern insulating film 132. The second channel pattern insulating film 162 may include a material having ferroelectricity more than that of the first channel pattern insulating film 132. For example, the first channel pattern insulating film 132 may not include hafnium oxide, and the second channel pattern insulating film 162 may include hafnium oxide. Alternatively, the hafnium oxide included in the (2_2)th insulating film 162b may include a crystal structure different from that of the oxide included in the first channel pattern insulating film 132. In detail, hafnium oxide included in the (2_2)th insulating film 162b may have a orthorhombic crystal structure, and hafnium oxide included in the first channel pattern insulating film 132 may have a crystal structure such as a cubic, tetragonal, or monoclinic.

A thickness T2 of the second channel pattern insulating film 162 in the second direction Y may be less than a thickness T1 of the first channel pattern insulating film 132 in the second direction Y. For example, the thickness T2 of the second channel pattern insulating film 162 may be 0.7 times or less than the thickness T1 of the first channel pattern insulating film 132.

In some embodiments, a hafnium oxide-based ferroelectric material may be introduced into the second channel pattern insulating film 162 to enhance the performance of the string selection transistor. The introduction of the hafnium oxide-based ferroelectric material may reduce an equivalent oxide thickness (EOT) of a gate insulating film, thereby lowering a program voltage required to control the flow of electrons in the memory cell. In addition, since electron movement may be efficiently controlled even at a lower voltage, unnecessary current flow may be blocked and a leakage current may be reduced.

The second filling pattern 164 may fill the inside of the second channel pattern 160. The second channel pattern 160 may surround an outer sidewall of the second filling pattern 164. The second filling pattern 164 may include an insulating material, for example, silicon oxide.

The second channel pad 166 may be electrically connected to an upper portion of the second channel pattern 160. The second channel pad 166 may include, for example, polysilicon doped with impurities.

In the third direction Z, the string selection channel structure SCH may overlap at least a portion of the channel structure CH. For example, based on the channel structure CH, the string selection channel structure SCH may be aligned in the third direction Z. Alternatively, based on the channel structure CH, the string selection channel structure SCH may not be completely aligned in the third direction Z, but may partially overlap the channel structure CH.

The mold structure MS may expose a portion of the upper surface of the source layer of the cell substrate 102 in the pad area PA. In the pad area PA, the source contact 174 may be electrically connected to the source layer of the cell substrate 102.

The first insulating film 108 may be disposed on the cell substrate 102. The first insulating film 108 may cover the lower surface of the cell substrate 102.

The first metal patterns 186a and 186e may be disposed on the string selection line SSL. The string selection channel structure SCH and the string selection line SSL may be electrically connected to the first metal patterns 186a and 186e.

For example, studs 182a and 184a may be sequentially disposed on the string selection channel structure SCH. The string selection channel structure SCH may be electrically connected to the first metal pattern 186a through the studs 182a and 184a. The first metal pattern 186a may be a bit line (e.g., BL of FIG. 2) of the semiconductor memory device. Studs 182e and 184e may be sequentially disposed on the string selection line SSL. The string selection line SSL may be electrically connected to the first metal pattern 186e through the studs 182e and 184e.

Each of the first to sixth interlayer insulating films 141 to 147 may include at least one of, for example, silicon oxide, silicon nitride, silicon oxynitride, or a low-k material having a dielectric constant lower than that of silicon oxide. For example, the third interlayer insulating film 143 may include a nitride-based insulating material, and the first and second interlayer insulating films 141 and 142 and the fourth to sixth interlayer insulating films 145 to 147 may include an oxide-based insulating material.

The peripheral circuit structure PERI may include a peripheral circuit board 200, a peripheral circuit element PT, a wiring structure PW, a second interconnection insulating film 240, a second bonding via 292, and a second bonding metal 294.

The peripheral circuit board 200 may include, for example, a semiconductor substrate such as a silicon substrate, a germanium substrate, or a silicon-germanium substrate. Alternatively, the peripheral circuit board 200 may include a silicon-on-insulator (SOI) substrate or a germanium-on-insulator (GOI) substrate.

The peripheral circuit element PT may be formed on the peripheral circuit board 200. The peripheral circuit element PT may constitute a peripheral circuit (e.g., the peripheral circuit 30 of FIG. 1) that controls an operation of the semiconductor memory device. For example, the peripheral circuit element PT may include a control logic (e.g., the control logic 37 of FIG. 1), a row decoder (e.g., the row decoder 33 of FIG. 1), a page buffer (e.g., the page buffer 35 of FIG. 1), and the like. In the following description, a surface of the peripheral circuit board 200, on which the peripheral circuit element PT is disposed, may be referred to as a front side of the peripheral circuit board 200. On the contrary, a surface of the peripheral circuit board 200, which is opposite to the front side of the peripheral circuit board 200, may be referred to as a back side of the peripheral circuit board 200.

The peripheral circuit element PT may include, for example, a transistor, but is not limited thereto. For example, the peripheral circuit element PT may include various passive elements such as a capacitor, a register, and an inductor as well as various active elements such as a transistor.

The wiring structure PW may be formed on the peripheral circuit element PT. For example, the second interconnection insulating film 240 may be formed on the front side of the peripheral circuit board 200, and the wiring structure PW may be formed in the second interconnection insulating film 240. The wiring structure PW may be electrically connected to the peripheral circuit element PT. The number and arrangement of layers of the shown wiring structure PW are only exemplary, and are not limited thereto.

The peripheral circuit structure PERI may be disposed on the memory cell structure CELL. In some embodiments, the front side of the peripheral circuit board 200 may face the front side of the cell substrate 102. The peripheral circuit structure PERI may be disposed on the front side of the cell substrate 102. The mold structure MS may be disposed between the cell substrate 102 and the peripheral circuit structure PERI.

The semiconductor memory device according to some embodiments may have a chip to chip (C2C) structure. The C2C structure refers to the configuration where a first chip including a memory cell structure CELL is manufactured on a first wafer (e.g., the cell substrate 102) and a second chip including a peripheral circuit structure PERI is manufactured on a separate second wafer (e.g., the peripheral circuit board 200). The first chip and the second chip are connected to each other by using a bonding method.

For example, the bonding method may include a method for electrically connecting a first bonding metal 194 formed on the uppermost metal layer of the first chip with a second bonding metal 294 formed on the uppermost metal layer of the second chip. For example, when the first bonding metal 194 and the second bonding metal 294 are formed of copper (Cu), the bonding method may be a Cu—Cu bonding method. However, this is only exemplary, and the first bonding metal 194 and the second bonding metal 294 may be formed of various other metals such as aluminum (Al) or tungsten (W).

As the first bonding metal 194 and the second bonding metal 294 are bonded to each other, the first metal patterns 186a and 186e may be connected to the wiring structure PW. The first metal patterns 186a and 186e may be electrically connected to the first bonding metal 194 through a first bonding via 192. The first bonding via 192 and the first bonding metal 194 may be disposed in the first interconnection insulating film 190. The wiring structure PW may be electrically connected to the second bonding metal 294 through a second bonding via 292. The second bonding via 292 and the second bonding metal 294 may be disposed in the second interconnection insulating film 240. Therefore, the first metal patterns 186a and 186e, the respective ground selection line GSL, the word lines WL1 to WLn, and the erase control line ECL or the string selection line SSL may be electrically connected to at least one of the peripheral circuit elements PT.

The second insulating film 208 may be disposed on the peripheral circuit board 200. The second insulating film 208 may cover the lower surface of the peripheral circuit board 200.

In some embodiments, the string selection channel structure SCH has been described as being formed within the string selection line SSL, but the technical spirits of the present disclosure are not limited thereto.

For example, a channel structure having the same structure as the string selection channel structure SCH of FIG. 7 may be formed within the ground selection line GSL or the dummy word line. In this case, unlike FIG. 4, the ground selection line GSL may be disposed on the channel structure CH like the string selection line SSL of FIG. 4.

In this case, the channel structure formed in the ground selection line GSL may include a channel pattern and a channel pattern insulating film surrounding the channel pattern. The channel pattern insulating film may include hafnium oxide containing at least one of silicon (Si), zirconium (Zr), aluminum (Al), lanthanum (La), niobium (Nb), or yttrium (Y).

The channel pattern insulating film may include hafnium oxide different from a material of the first channel pattern insulating film 132. The channel pattern insulating film may include a material with higher ferroelectricity compared to a material of the first channel pattern insulating film 132. The channel pattern insulating film may include hafnium oxide having an orthorhombic crystal structure.

A thickness of the channel pattern insulating film in the second direction Y may be less than a thickness of the first channel pattern insulating film 132 in the second direction Y.

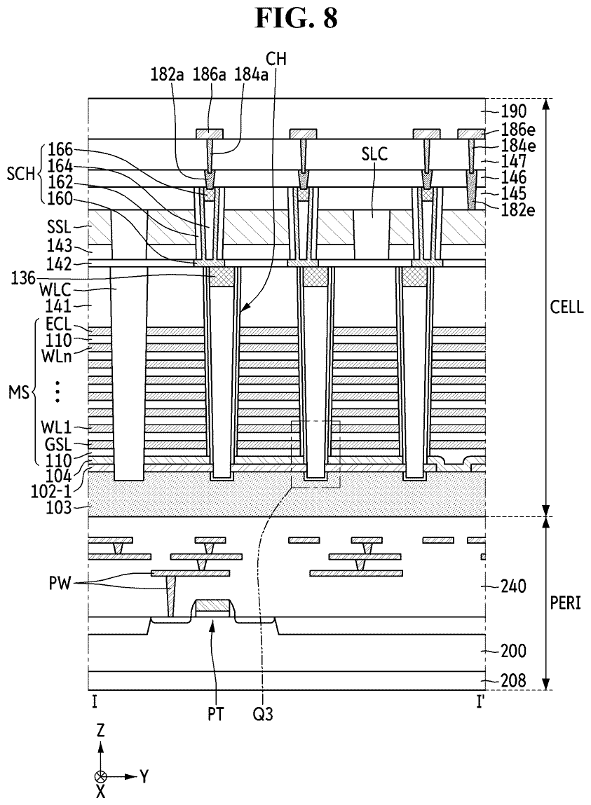

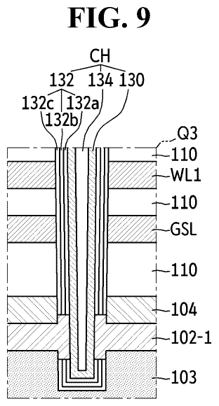

FIG. 8 is another exemplary cross-sectional view illustrating a semiconductor memory device according to some embodiments. FIG. 9 is an enlarged view illustrating a region Q3 of FIG. 8. For reference, FIG. 8 is another cross-sectional view taken along line I-I′ of FIG. 3. For convenience of description, redundant portions of those described above with reference to FIGS. 1 to 7 will be briefly described or omitted.

Referring to FIGS. 8 and 9, in the semiconductor memory device according to some embodiments, the memory cell structure CELL may include a source layer 102-1, a semiconductor layer 103, and a support layer 104. For example, the source layer 102-1, the semiconductor layer 103, and the support layer 104 may be provided in the cell array area CA.

The semiconductor layer 103 may include, for example, a semiconductor substrate such as a silicon substrate, a germanium substrate or a silicon-germanium substrate. Alternatively, the semiconductor layer 103 may include a silicon-on-insulator (SOI) substrate or a germanium-on-insulator (GOI) substrate. The semiconductor layer 103 may include, for example, polysilicon doped with impurities, metal or metal silicide. The semiconductor layer 103 may be formed of a multi-layer.

The source layer 102-1 may be interposed between the semiconductor layer 103 and the mold structure MS. The source layer 102-1 may extend to be conformal along an upper surface of the semiconductor layer 103. The source layer 102-1 may be electrically connected to the first channel pattern 130 of each channel structure CH. For example, as shown in FIG. 9, the channel structure CH may pass through the source layer 102-1. A lower portion of the channel structure CH may be disposed in the semiconductor layer 103. The source layer 102-1 may be in contact with the side of the first channel pattern 130 by passing through the first channel pattern insulating film 132.

In some embodiments, a portion of the source layer 102-1 adjacent to the first channel pattern 130 may have a shape protruded toward the first channel pattern insulating film 132. For example, in an area adjacent to the first channel pattern 130, a length of the source layer 102-1 extended in the third direction Z may be longer. As a result, the source layer 102-1 may be in contact with the first channel pattern 130 at a larger area.

In some embodiments, a base insulating film may be interposed between the semiconductor layer 103 and the source layer 102-1. The base insulating film may include at least one of, for example, silicon oxide, silicon nitride, or silicon oxynitride, but is not limited thereto.

The support layer 104 may be formed on the semiconductor layer 103 and the source layer 102-1. The support layer 104 may be interposed between the source layer 102-1 and the mold structure MS. For example, the support layer 104 may extend to be conformal along the upper surface of the semiconductor layer 103 and the upper surface of the source layer 102-1. The support layer 104 may include, for example, polysilicon.

The support layer 104 may be used as a support for preventing the mold stack from being destroyed or collapsed in a replacement process for forming the source layer 102-1. For example, the source layer 102-1 may expose a portion of the upper surface of the semiconductor layer 103, and a portion of the support layer 104 may extend along the exposed upper surface of the semiconductor layer 103 to contact the upper surface of the semiconductor layer 103.

The semiconductor layer 103, the source layer 102-1 and the support layer 104 may be provided as a common source line (e.g., CSL of FIG. 2) of the semiconductor memory device.

The word line cutting structure WLC may cut the source layer 102-1 and the support layer 104. For example, the lower surface of the word line cutting structure WLC may be disposed below the lower surface of the source layer 102-1. For another example, the lower surface of the word line cutting structure WLC may be disposed on substantially the same plane as the lower surface of the source layer 102-1.

In the semiconductor memory device according to some embodiments, the front side of the peripheral circuit board 200 may face the back sides of the source layer 102-1, the semiconductor layer 103, and the support layer 104. The peripheral circuit structure PERI may be disposed on the back sides of the source layer 102-1, the semiconductor layer 103, and the support layer 104. The source layer 102-1, the semiconductor layer 103, and the support layer 104 may be disposed between the mold structure MS and the peripheral circuit structure PERI.

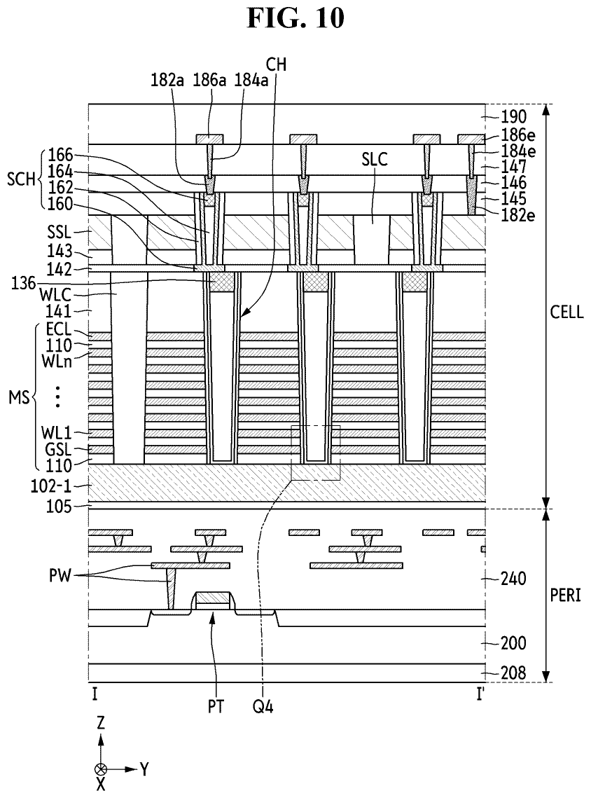

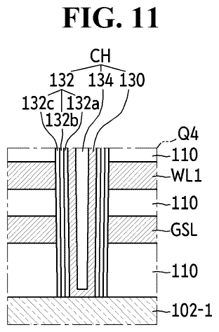

FIG. 10 is another exemplary cross-sectional view illustrating a semiconductor memory device according to some embodiments. FIG. 11 is an enlarged view illustrating a region Q4 of FIG. 10. For reference, FIG. 10 is another cross-sectional view taken along line I-I′ of FIG. 3. For convenience of description, redundant portions of those described above with reference to FIGS. 8 and 9 will be briefly described or omitted.

Referring to FIGS. 10 and 11, in the semiconductor memory device according to some embodiments, a lower surface of the first channel pattern 130 of the channel structure CH may be in contact with the source layer 102-1. The source layer 102-1 may be in further contact with a lower surface of the first channel pattern insulating film 132. The channel structure CH may not pass through the source layer 102-1.

In some embodiments, the memory cell structure CELL may further include a metal silicide layer 105 disposed between the source layer 102-1 and the peripheral circuit structure PERI.

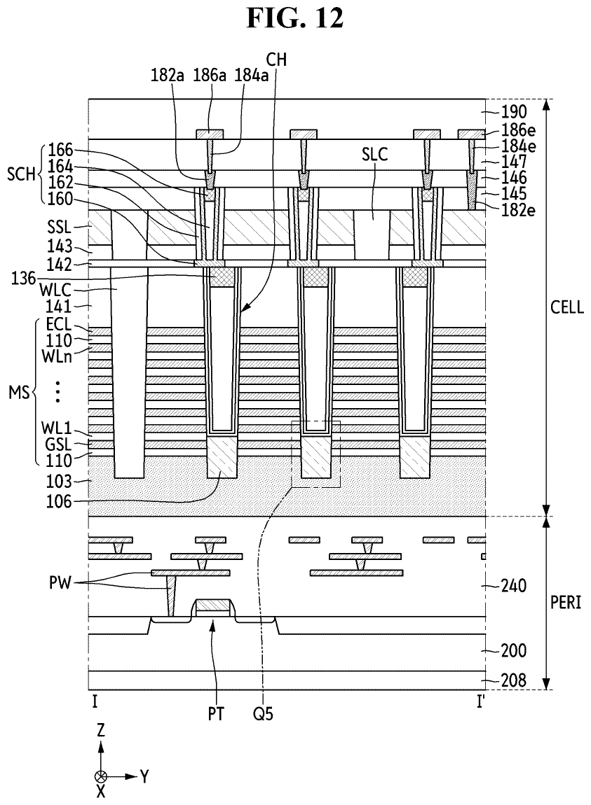

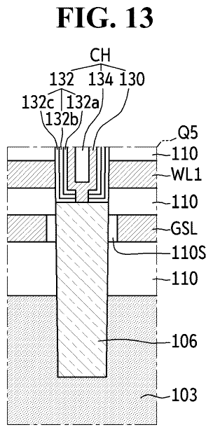

FIG. 12 is another exemplary cross-sectional view illustrating a semiconductor memory device according to some embodiments. FIG. 13 is an enlarged view illustrating a region Q5 of FIG. 12. For reference, FIG. 12 is another cross-sectional view taken along line I-I′ of FIG. 3. For convenience of description, redundant portions of those described above with reference to FIGS. 1 to 11 will be briefly described or omitted.

Referring to FIGS. 12 and 13, the semiconductor memory device according to some embodiments may include a source pattern 106. The source pattern 106 may be disposed on the semiconductor layer 103. The source pattern 106 may be electrically connected to the first channel pattern 130 of the channel structure CH. For example, the first channel pattern 130 may be in contact with an upper surface of the source pattern 106 by passing through the first channel pattern insulating film 132. The source pattern 106 and the semiconductor layer 103 may be provided as a common source line (e.g., CSL of FIG. 2) of the semiconductor memory device.

The source pattern 106 may include a conductive material, for example, polysilicon doped with impurities or metal, but is not limited thereto. The source pattern 106 may be formed by, for example, a selective epitaxial growth process from the semiconductor layer 103, but is not limited thereto.

For example, a lower portion of the source pattern 106 may be buried in the semiconductor layer 103. For another example, the lower surface of the source pattern 106 may be disposed on substantially the same plane as the upper surface of the semiconductor layer 103.

In some embodiments, the upper surface of the source pattern 106 may cross a portion of the ground selection line GSL, the word lines WL1 to WLn, and the erase control line ECL. For example, the upper surface of the source pattern 106 may be formed to be higher than an upper surface of the ground selection line GSL. In this case, a gate insulating film 110S may be interposed between the source pattern 106 and the gate electrode (e.g., the ground selection line GSL) crossing the source pattern 106.

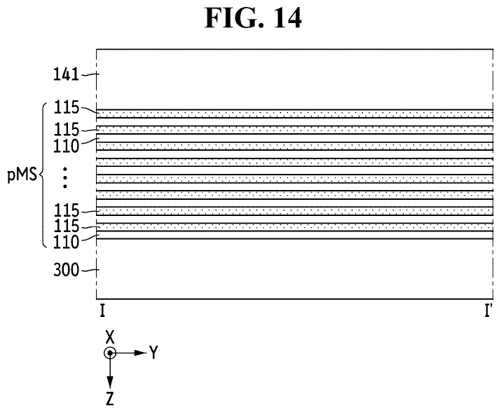

FIGS. 14 to 23 are views illustrating a method of fabricating a semiconductor memory device according to some embodiments. For convenience of description, redundant portions of those described above with reference to FIGS. 1 to 7 will be briefly described or omitted.

Referring to FIG. 14, a substrate 300 including a cell array area (CA of FIG. 3) may be provided.

A pre-mold structure pMS may be formed on a front side of the substrate 300. The pre-mold structure pMS may include a plurality of mold insulating films 110 and a plurality of mold sacrificial films 115, which are alternately stacked on the substrate 300. The pre-mold structure pMS on the extension area (EXT of FIG. 3) may be patterned in a stepwise shape. Accordingly, each of the mold sacrificial films 115 on the extension area EXT may include an area of which upper surface is exposed on the extension area EXT. In the following description, a surface of the substrate 300, on which the pre-mold structure pMS is formed, may be referred to as a front side of the substrate 300. In contrast, a surface of the substrate 300, which is opposite to the front side of the substrate 300, may be referred to as a back side of the substrate 300.

The mold sacrificial film 115 may include a material having etch selectivity with respect to the mold insulating film 110. For example, the mold insulating film 110 may include silicon oxide, and the mold sacrificial film 115 may include silicon nitride.

The first interlayer insulating film 141 covering the substrate 300 and the pre-mold structure pMS may be formed.

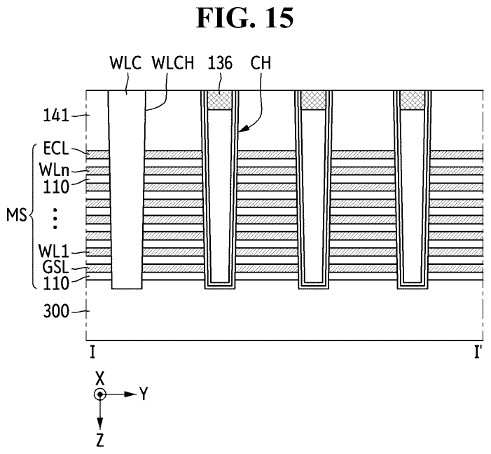

Referring to FIG. 15, the channel structure CH passing through the pre-mold structure pMS may be formed on the cell array area (CA of FIG. 3) of the substrate 300. After a channel hole passing through the pre-mold structure pMS is formed, the channel structure CH filling the channel hole may be formed. The channel structure CH may be disposed in the substrate 300 of the lower surface of the channel structure CH. The channel structure CH may include a first channel pad 136 formed on an upper portion thereof.

The ground selection line GSL, the word lines WL1 to WLn, and the erase control line ECL may be formed. The ground selection line GSL, the word lines WL1 to WLn, and the erase control line ECL may be formed by a replacement process. The mold sacrificial film 115 exposed by the word line cutting structure WLC may be selectively removed. Subsequently, the ground selection line GSL, the word lines WL1 to WLn, and the erase control line ECL may be formed to replace the area from which the mold sacrificial film 115 is removed. As a result, the mold structure MS including the plurality of ground selection line GSL, the word lines WL1 to WLn, and the erase control line ECL may be formed. After the mold structure MS is formed, the word line cutting structure WLC filling a word line cutting hole WLCH may be formed.

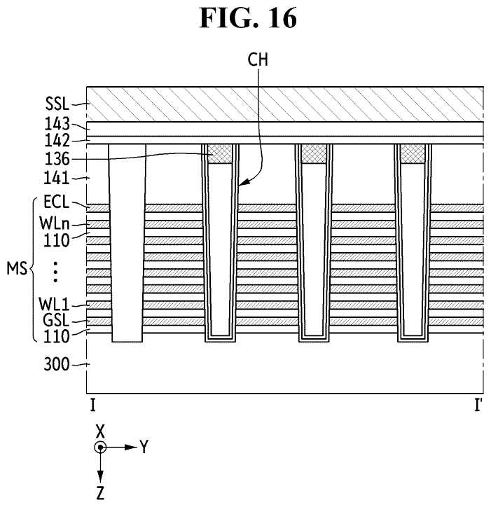

Referring to FIG. 16, the second interlayer insulating film 142, the third interlayer insulating film 143 and the string selection line SSL may be sequentially formed on the first interlayer insulating film 141.

The third interlayer insulating film 143 may include a material having etch selectivity with respect to the second interlayer insulating film 142. For example, the second interlayer insulating film 142 may include silicon oxide, and the third interlayer insulating film 143 may include silicon nitride.

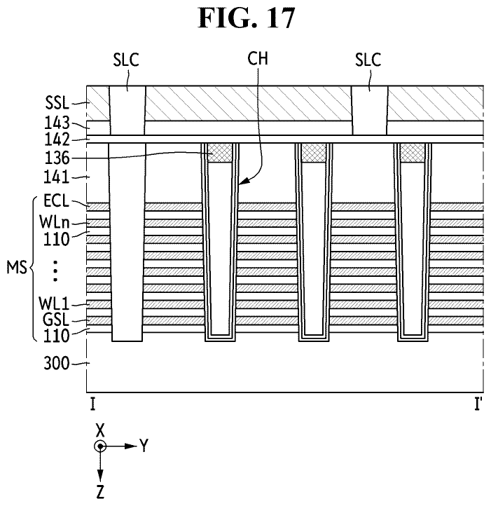

Referring to FIG. 17, the string separation structure SLC for separating the string selection line SSL may be formed on the cell array area (CA of FIG. 3) of the substrate 300. For example, a lower surface of the string separation structure SLC may be disposed above an upper surface of the first interlayer insulating film 141.

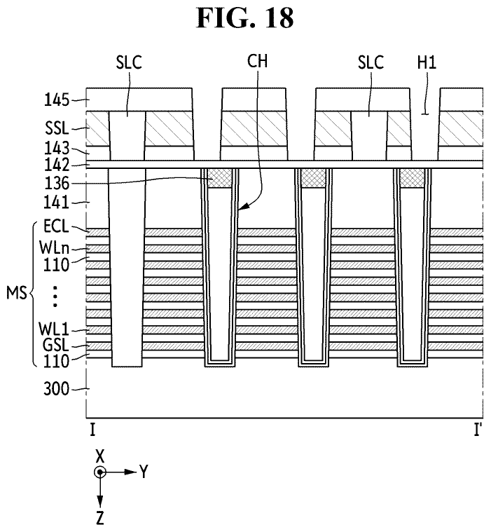

Referring to FIG. 18, the fourth interlayer insulating film 145 may be formed on the string selection line SSL.

A first hole H1 passing through the fourth interlayer insulating film 145, the string selection line SSL and the third interlayer insulating film 143 may be formed. The first hole H1 may overlap a portion of the channel structure CH in the third direction Z perpendicular to the front side of the substrate 300. The first hole H1 may expose the second interlayer insulating film 142. The first hole H1 may be shifted in a direction away from the string separation structure SLC that does not overlap the word line cutting structure WLC. For example, based on the center of the channel structure CH, the center of the first hole H1 may be shifted in a direction away from the string separation structure SLC that does not overlap the word line cutting structure WLC in the third direction Z.

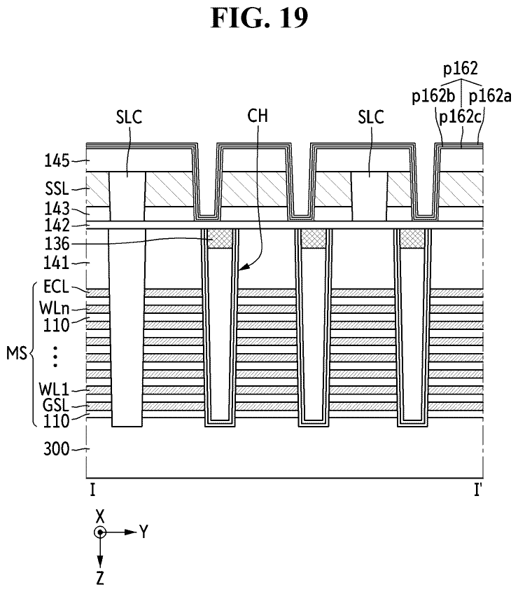

Referring to FIG. 19, a pre-channel pattern insulating film p162 may be formed along sidewalls and a bottom surface of the first hole H1. The pre-channel pattern insulating film p162 may include a (2_3)th pre-insulating film p162c, a (2_2)th pre-insulating film p162b and a (2_1)th pre-insulating film p162a, which are sequentially stacked on the sidewalls and the bottom surface of the first hole H1.

The (2_1)th pre-insulating film p162a may include oxide, the (2_2)th pre-insulating film p162b may include hafnium oxide, and the (2_3)th pre-insulating film p162c may include oxide.

The (2_1)th pre-insulating film p162a may include, for example, silicon oxide or a high-k material (e.g., aluminum oxide (Al₂O₃) or hafnium oxide (HfO₂)) having a dielectric constant higher than that of silicon oxide. The (2_2)th pre-insulating film p162b may include hafnium oxide containing at least one of silicon (Si), zirconium (Zr), aluminum (Al), lanthanum (La), niobium (Nb) or yttrium (Y). For example, the (2_3)th pre-insulating film p162c may include, for example, silicon oxide or a high-k material (e.g., aluminum oxide (Al₂O₃) or hafnium oxide (HfO₂)) having a dielectric constant higher than that of silicon oxide.

The pre-channel pattern insulating film p162 may include hafnium oxide different from that of the first channel pattern insulating film 132. The pre-channel pattern insulating film p162 may include oxide having ferroelectricity more than that of the first channel pattern insulating film 132. For example, the hafnium oxide included in the pre-channel pattern insulating film p162 may include a crystal structure different from that of the oxide included in the first channel pattern insulating film 132.

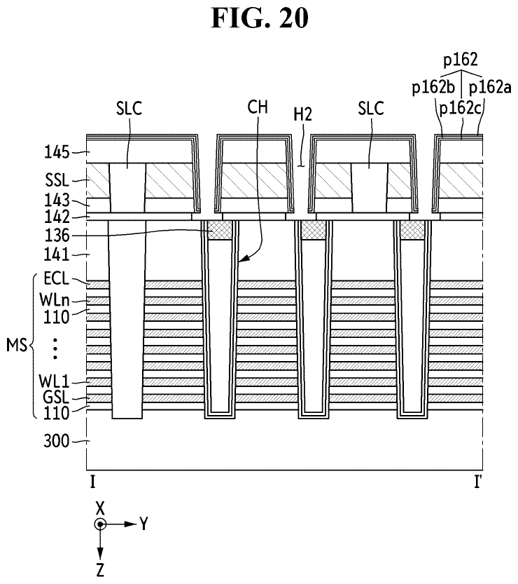

Referring to FIG. 20, the second interlayer insulating film 142 may be removed through the first hole H1 to form an extension hole H2. A portion of the second interlayer insulating film 142 exposed by the first hole H1 may be removed so that the extension hole H2 may be formed. The extension hole H2 may expose a portion of the upper surface of the channel structure CH. The extension hole H2 may expose a portion of the upper surface of the first channel pattern 130 and a portion of the upper surface of the first channel pad 136.

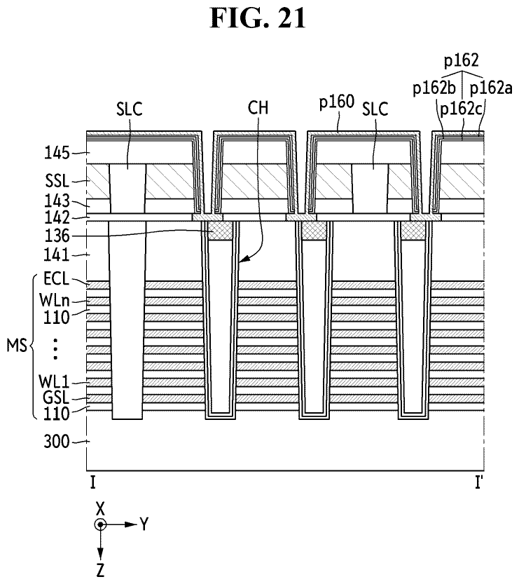

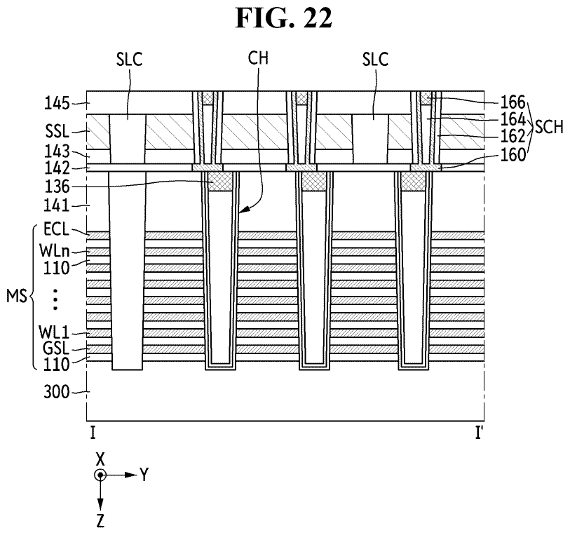

Referring to FIGS. 21 and 22, a pre-second channel pattern insulating film p160 may be formed on a pre-channel pattern insulating film p162. The pre-second channel pattern insulating film p160 may be formed along a sidewall of the exposed 2_1th pre-insulating film p162a and may be formed within at least a portion of the extension hole H2. The string selection channel structure SCH may be formed in the first hole H1 and the extension hole H2. The string selection channel structure SCH may include a second channel pattern 160, a second channel pattern insulating film 162, a second filling pattern 164, and a second channel pad 166. The second channel pattern 160 may be in contact with the channel structure CH.

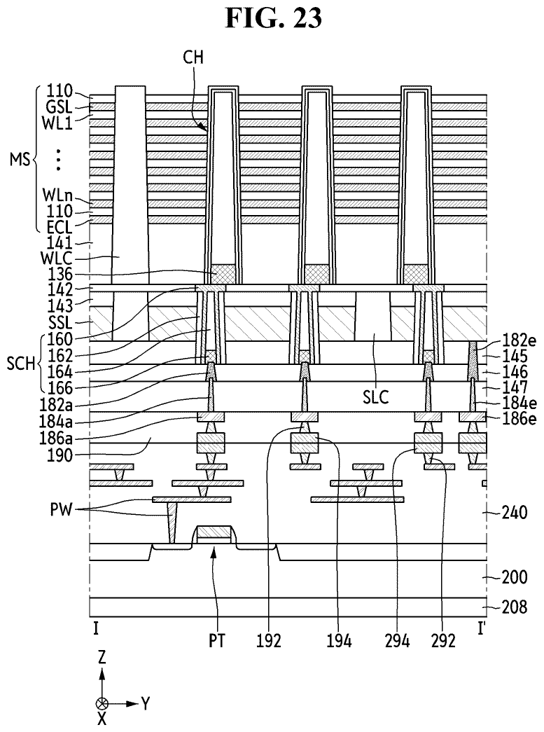

Referring to FIG. 23, the stud 182e may be formed in the second to fourth interlayer insulating films 142 to 145. The fifth and sixth interlayer insulating films 146 and 147 may be sequentially formed on the fourth interlayer insulating film 145. The studs 182a and 182e may be formed in the fifth interlayer insulating film 146. The studs 184a and 184e may be formed in the sixth interlayer insulating film 147. The first interconnection insulating film 190 may be formed on the sixth interconnection insulating film 147. The first metal patterns 186a and 186e, the first bonding via 192 and the first bonding metal 194 may be formed in the first interconnection insulating film 190.

The peripheral circuit structure PERI may be provided. The peripheral circuit structure PERI may include a peripheral circuit board 200, a peripheral circuit element PT, a wiring structure PW, a second interconnection insulating film 240, a second bonding via 292, and a second bonding metal 294.

The peripheral circuit structure PERI may be bonded on the front side of the substrate 300. The first bonding metal 194 and the second bonding metal 294 may be bonded to each other.

The substrate 300 may be removed. Accordingly, the lower portion of the channel structure CH may be exposed.

Subsequently, referring to FIG. 4, a portion of the first channel pattern insulating film 132 of the exposed channel structure CH may be removed. For this reason, the first channel pattern 130 may be exposed. The lower surface of the first channel pattern 130 and a portion of the sidewalls of the first channel pattern 130 may be exposed.

The cell substrate 102 covering the word line cutting structure WLC and the channel structure CH may be formed. The source layer 102-1 of the cell substrate 102 may be in contact with the first channel pattern 130 of the channel structure CH. Accordingly, the channel structure CH may be electrically connected to the source layer 102-1 of the cell substrate 102.

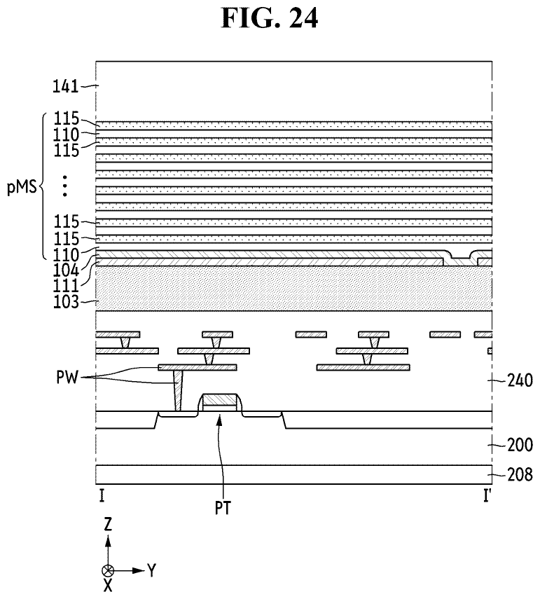

FIGS. 24 to 26 are views illustrating a method of fabricating a semiconductor memory device according to some embodiments. For convenience of description, redundant portions of those described above with reference to FIGS. 1 to 23 will be briefly described or omitted.

Referring to FIG. 24, the peripheral circuit structure PERI may be provided. A pre-cell substrate and a pre-mold structure pMS may be formed on the peripheral circuit structure PERI. The pre-cell substrate may include a semiconductor layer 103, a source sacrificial film 111, and a support layer 104. The source sacrificial film 111 and the support layer 104 may be formed on the semiconductor layer 103. The source sacrificial film 111 may include a material having etch selectivity with respect to the mold insulating film 110. The support layer 104 may include a material having etch selectivity with respect to the source sacrificial film 111. For example, the source sacrificial film 111 may include a silicon nitride layer, and the support layer 104 may include polysilicon.

The pre-molded structure pMS may be formed on the pre-cell substrate. The first interlayer insulating film 141 covering the pre-cell substrate and the pre-molded structure pMS may be formed.

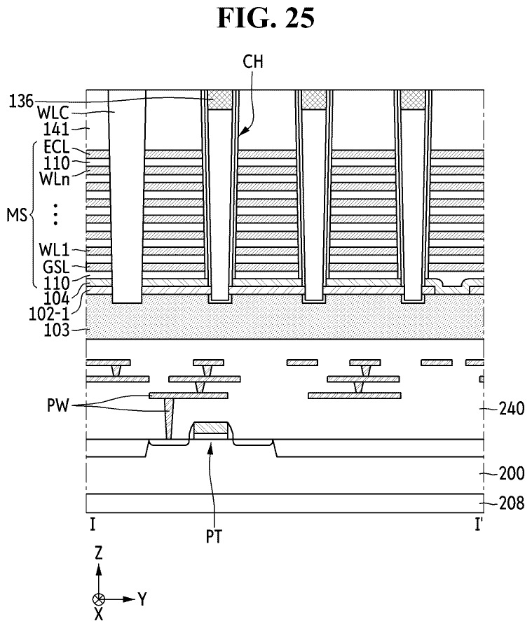

Referring to FIG. 25, the channel structure CH passing through the pre-mold structure (pMS of FIG. 24) may be formed on the cell array area (CA of FIG. 3) of the substrate 300.

A word line cutting hole passing through the pre-mold structure (pMS of FIG. 24) may be formed on the cell array area (CA of FIG. 3) of the substrate 300. The mold sacrificial film 115 exposed by the word line cutting structure WLC may be selectively removed through the word line cutting hole, and the ground selection line GSL, the word lines WL1 to WLn, and the erase control line ECL may be formed to replace the area from which the mold sacrificial film 115 is removed.

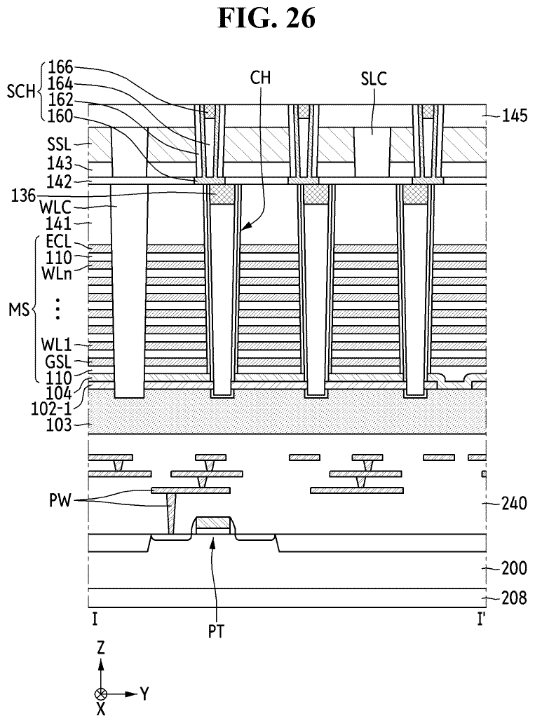

Referring to FIG. 26, the string selection line SSL, the first to fourth interlayer insulating films 141 to 145, the string separation structure SLC and the string selection channel structure SCH may be formed.

Referring to FIG. 8, the stud 182e may be formed in the second to fourth interlayer insulating films 142 to 145. The fifth and sixth interlayer insulating films 146 and 147 may be sequentially formed on the fourth interlayer insulating film 145. The studs 182a and 182e may be formed in the fifth interlayer insulating film 146. The studs 184a and 184e may be formed in the sixth interlayer insulating film 147. The first interconnection insulating film 190 may be formed on the sixth interlayer insulating film 147. The first metal patterns 186a and 186e may be formed in the first interconnection insulating film 190.

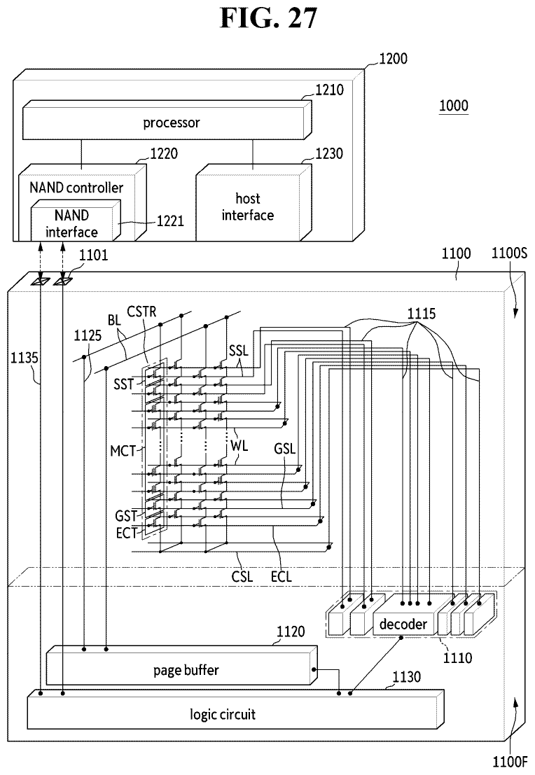

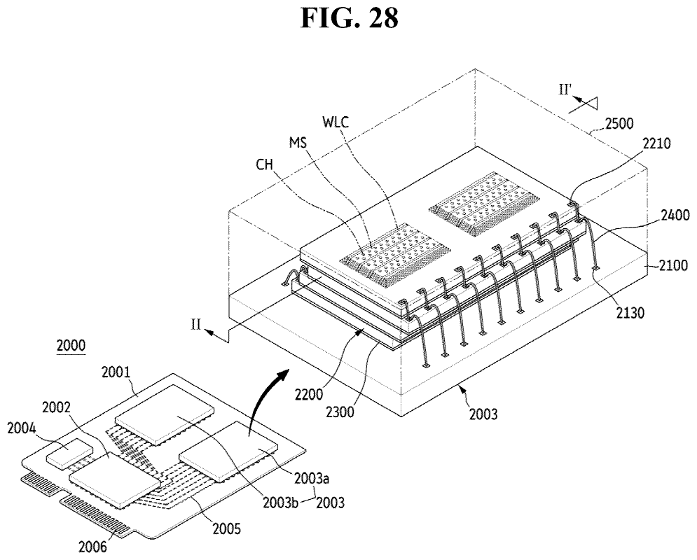

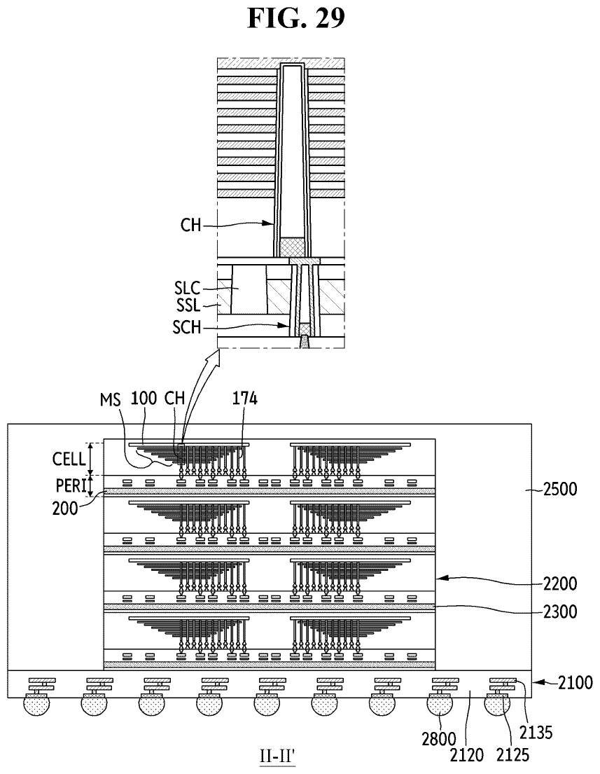

FIG. 27 is an exemplary block diagram illustrating an electronic system according to some embodiments. FIG. 28 is an exemplary perspective view illustrating an electronic system according to some embodiments. FIG. 29 is a schematic cross-sectional view taken along line II-II′ of FIG. 28.

Referring to FIG. 27, an electronic system 1000 according to some embodiments may include a nonvolatile memory device 1100 and a controller 1200 electrically connected to the nonvolatile memory device 1100. The electronic system 1000 may be a storage device including one or a plurality of nonvolatile memory devices 1100 or an electronic device including the storage device. For example, the electronic system 1000 may be a solid state drive (SSD) device, a universal serial bus (USB), a computing system, a medical device or a communication device, which includes one or a plurality of nonvolatile memory devices 1100.

The nonvolatile memory device 1100 may be a NAND flash memory device, and may be, for example, the nonvolatile memory device described with reference to FIGS. 1 to 13. The nonvolatile memory device 1100 may include a first structure 1100F and a second structure 1100S on the first structure 1100F.

The first structure 1100F may be a peripheral circuit structure that includes a decoder circuit 1110 (e.g., row decoder 33 of FIG. 8), a page buffer 1120 (e.g., page buffer 35 of FIG. 1) and a logic circuit 1130 (e.g., control logic 37 of FIG. 1).

The second structure 1100S may include a common source line CSL, a plurality of bit lines BL and a plurality of cell strings CSTR, which are described above with reference to FIG. 2. The cell strings CSTR may be connected to the decoder circuit 1110 through a word line WL, at least one string selection line SSL and at least one ground selection line GSL. In addition, the cell strings CSTR may be connected to the page buffer 1120 through the bit lines BL.

In some embodiments, the common source line CSL and the cell strings CSTR may be electrically connected to the decoder circuit 1110 through first connection lines 1115 extended from the first structure 1100F to the second structure 1100S.

In some embodiments, the bit lines BL may be electrically connected to the page buffer 1120 through second connection lines 1125 extended from the first structure 1100F to the second structure 1100S.

The nonvolatile memory device 1100 may perform communication with the controller 1200 through an input/output pad 1101 electrically connected to the logic circuit 1130 (e.g., the control logic 37 of FIG. 1). The input/output pad 1101 may be electrically connected to the logic circuit 1130 through an input/output connection line 1135 extended from the first structure 1100F to the second structure 1100S.

The controller 1200 may include a processor 1210, a NAND controller 1220 and a host interface 1230. In some embodiments, the electronic system 1000 may include a plurality of nonvolatile memory devices 1100, and in this case, the controller 1200 may control the plurality of nonvolatile memory devices 1100.

The processor 1210 may control the overall operation of the electronic system 1000 including the controller 1200. The processor 1210 may operate in accordance with predetermined firmware, and may access the nonvolatile memory device 1100 by controlling the NAND controller 1220. The NAND controller 1220 may include a NAND interface 1221 that processes communication with the nonvolatile memory device 1100. A control command for controlling the nonvolatile memory device 1100, data to be written in the memory cell transistors MCT of the nonvolatile memory device 1100, data to be read from the memory cell transistors MCT of the nonvolatile memory device 1100, etc. may be transmitted through the NAND interface 1221. The host interface 1230 may provide a communication function between the electronic system 1000 and an external host. When the control command is received from the external host through the host interface 1230, the processor 1210 may control the nonvolatile memory device 1100 in response to the control command.

Referring to FIGS. 27 to 29, an electronic system according to some embodiments may include a main board 2001, a main controller 2002 packaged on the main board 2001, one or more semiconductor packages 2003 and a DRAM 2004. The semiconductor package 2003 and the DRAM 2004 may be connected to the main controller 2002 by wiring patterns 2005 formed in the main board 2001.

The main board 2001 may include a connector 2006 that includes a plurality of pins coupled to the external host. The number and arrangement of the plurality of pins in the connector 2006 may be varied depending on the communication interface between the electronic system 2000 and the external host. In some embodiments, the electronic system 2000 may perform communication with the external host in accordance with any one of interfaces such as a Universal Serial Bus (USB), a Peripheral Component Interconnect Express (PCI-Express), Serial Advanced Technology Attachment (SATA) and M-Phy for Universal Flash Storage (UFS). In some embodiments, the electronic system 2000 may operate by a power source supplied from the external host through the connector 2006. The electronic system 2000 may further include a power management integrated circuit (PMIC) that distributes the power source supplied from the external host to the main controller 2002 and the semiconductor package 2003.

The main controller 2002 may write data in the semiconductor package 2003 or read the data from the semiconductor package 2003, and may improve the operating speed of the electronic system 2000.

The DRAM 2004 may be a buffer memory for mitigating a speed difference between the semiconductor package 2003 that is a data storage space and the external host. Also, the DRAM 2004 included in the electronic system 2000 may operate as a kind of a cache memory, and may provide a space for temporarily storing data in a control operation for the semiconductor package 2003. When the DRAM 2004 is included in the electronic system 2000, the main controller 2002 may further include a DRAM controller for controlling the DRAM 2004, in addition to the NAND controller for controlling the semiconductor package 2003.

The semiconductor package 2003 may include a first semiconductor package 2003a and a second semiconductor package 2003b, which are spaced apart from each other. Each of the first semiconductor package 2003a and the second semiconductor package 2003b may be a semiconductor package that includes a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a lower surface of each of the semiconductor chips 2200, a connection structure 2400 for electrically connecting the semiconductor chips 2200 with the package substrate 2100, and a molding layer 2500 covering the semiconductor chips 2200 and the connection structure 2400 on the package substrate 2100.

The package substrate 2100 may be a printed circuit board that includes package upper pads 2130. Each semiconductor chip 2200 may include an input/output pad 2210. The input/output pad 2210 may correspond to the input/output pad 1101 of FIG. 27.

In some embodiments, the connection structure 2400 may be a bonding wire for electrically connecting the input/output pad 2210 with the package upper pads 2130. Therefore, in each of the first semiconductor package 2003a and the second semiconductor package 2003b, the semiconductor chips 2200 may be electrically connected to each other in a bonding wire manner, and may be electrically connected to the package upper pads 2130 of the package substrate 2100. In some embodiments, in each of the first semiconductor package 2003a and the second semiconductor package 2003b, the semiconductor chips 2200 may be electrically connected to each other by a connection structure that includes a through silicon via TSV, instead of the connection structure 2400 of the bonding wire manner.

In some embodiments, the main controller 2002 and the semiconductor chips 2200 may be included in one package. In some embodiments, the main controller 2002 and the semiconductor chips 2200 may be packaged on a separate interposer substrate different from the main board 2001, and the main controller 2002 may be connected with the semiconductor chips 2200 by a wire formed in the interposer substrate.

In some embodiments, the package substrate 2100 may be a printed circuit board. The package substrate 2100 may include a package substrate body portion 2120, package upper pads 2130 disposed on an upper surface of the package substrate body portion 2120, lower pads 2125 disposed on a lower surface of the package substrate body portion 2120 or exposed through the lower surface, and internal wires 2135 electrically connecting the upper pads 2130 with the lower pads 2125 inside the package substrate body portion 2120. The upper pads 2130 may be electrically connected to the connection structures 2400. The lower pads 2125 may be connected to the wiring patterns 2005 of the main board 2001 of the electronic system 2000 through conductive connectors 2800 as shown in FIG. 28.

Referring to FIGS. 28 and 29, in the electronic system according to some embodiments, each of the semiconductor chips 2200 may include the nonvolatile memory device described with reference to FIGS. 1 to 13. For example, each of the semiconductor chips 2200 may include a peripheral circuit structure PERI and a memory cell structure CELL. For example, the peripheral circuit structure PERI may include the peripheral circuit board 200 described with reference to FIGS. 1 to 13. Also, for example, the memory cell structure CELL may include the cell substrate, the mold structure MS, the channel structure CH, the string selection channel structure SCH, the string separation structure SLC, and the cell contact 170, which are described with reference to FIGS. 1 to 13.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A semiconductor memory device comprising:
a cell substrate;
a mold structure comprising a plurality of gate electrodes stacked on the cell substrate;
a channel structure passing through the mold structure;
a string selection line disposed on an upper surface of the channel structure; and
a string selection channel structure that passes through the string selection line and is in contact with the channel structure,
wherein the string selection channel structure comprises hafnium oxide that is different from a material of the channel structure.

2. The semiconductor memory device of claim 1, wherein the material of the channel structure omits hafnium oxide.

3. The semiconductor memory device of claim 1, wherein the hafnium oxide in the string selection channel structure has a crystal structure that is different from a structure of the hafnium oxide included in the channel structure.

4. The semiconductor memory device of claim 1, wherein the string selection channel structure comprises:
a first filling pattern;
a first channel pattern that surrounds the first filling pattern and is electrically connected to the channel structure; and
a first channel pattern insulating film between the first channel pattern and the string selection line, and
wherein the first channel pattern insulating film comprises a first insulating film, a second insulating film and a third insulating film, which are sequentially stacked on an outer side of the first channel pattern.

5. The semiconductor memory device of claim 4, wherein the second insulating film comprises hafnium oxide containing at least one of silicon (Si), zirconium (Zr), aluminum (Al), lanthanum (La), niobium (Nb), or yttrium (Y).

6. The semiconductor memory device of claim 1, wherein the string selection channel structure overlaps at least a portion of the channel structure.

7. The semiconductor memory device of claim 1, further comprising:
a stud; and
a bit line on the stud,
wherein the stud is disposed on the string selection channel structure.

8. The semiconductor memory device of claim 1, wherein the plurality of gate electrodes comprises a metal material, and
the string selection line comprises a semiconductor material.

9. The semiconductor memory device of claim 1, wherein the channel structure comprises:
a second filling pattern;
a second channel pattern surrounding the second filling pattern; and
a second channel pattern insulating film between the second channel pattern and the plurality of gate electrodes, and
wherein the second channel pattern insulating film comprises at least three insulating films, which are sequentially stacked on an outer side of the second channel pattern.

10. The semiconductor memory device of claim 1, further comprising:
a peripheral circuit board;
a peripheral circuit element on the peripheral circuit board; and
a peripheral circuit structure on the peripheral circuit board,
wherein the peripheral circuit structure comprises a wiring structure electrically connected to the peripheral circuit element, and the cell substrate is disposed between the mold structure and the peripheral circuit structure.

11. The semiconductor memory device of claim 1, further comprising:
a peripheral circuit board;
a peripheral circuit element on the peripheral circuit board; and
a peripheral circuit structure on the peripheral circuit board,
wherein the peripheral circuit structure comprises a wiring structure electrically connected to the peripheral circuit element, and the mold structure is disposed between the cell substrate and the peripheral circuit structure.

12. A semiconductor memory device comprising:
a cell substrate;
a mold structure comprising a plurality of gate electrodes stacked on the cell substrate;
a channel structure extending to the cell substrate by passing through the mold structure;
a string selection line disposed on the channel structure; and
a string selection channel structure extending to the cell substrate from the channel structure by passing through the string selection line,
wherein the channel structure comprises:
a first channel pattern; and
a first channel pattern insulating film between the first channel pattern and the plurality of gate electrodes,
wherein the string selection channel structure comprises
a second channel pattern connected to the channel structure; and
a second channel pattern insulating film that comprises a ferroelectric material and is provided between the second channel pattern and the string selection line, and wherein a thickness of the second channel pattern insulating film is less than a thickness of the first channel pattern insulating film.

13. The semiconductor memory device of claim 12, wherein the channel structure further comprises a first channel pad on the first channel pattern, and
the first channel pad is connected to the first channel pattern and in contact with the second channel pattern.

14. The semiconductor memory device of claim 12, wherein the second channel pattern insulating film comprises hafnium oxide different from a material of the first channel pattern insulating film.

15. The semiconductor memory device of claim 12, wherein the thickness of the second channel pattern insulating film is 0.7 times or less than a thickness of the first channel pattern insulating film.

16. The semiconductor memory device of claim 12, wherein the second channel pattern insulating film comprises hafnium oxide doped with at least one of silicon (Si) or zirconium (Zr).

17. The semiconductor memory device of claim 12, wherein the second channel pattern insulating film comprises hafnium oxide doped with at least one of lanthanum (La), niobium (Nb) or yttrium (Y).

18. The semiconductor memory device of claim 12, further comprising a plurality of string separation structures that separates the string selection lines and is provided on the mold structure.

19. An electronic system comprising:
a main board;
a semiconductor memory device on the main board; and
a processor that is electrically connected to the semiconductor memory device and is provided on the main board,
wherein the semiconductor memory device comprises:
a cell substrate;
a mold structure comprising a plurality of gate electrodes stacked on the cell substrate;
a first channel structure extending to the cell substrate by passing through the mold structure;
a conductive line on the first channel structure; and
a second channel structure extending to the cell substrate from the first channel structure by passing through the conductive line,
wherein the first channel structure comprises:
a first filling pattern;
a first channel pattern surrounding the first filling pattern; and
a first channel pattern insulating film between the first channel pattern and the plurality of gate electrodes,
wherein the second channel structure comprises:
a second filling pattern;
a second channel pattern surrounding the second filling pattern and being in contact with the first channel structure, and
a second channel pattern insulating film between the second channel pattern and the conductive line,
wherein a thickness of the second channel pattern insulating film is less than a thickness of the first channel pattern insulating film, and
wherein the second channel pattern insulating film comprises a ferroelectric material that is different from a material of the first channel pattern insulating film.

20. The electronic system of claim 19, wherein the conductive line is a ground selection line.
